(19) United States
(12) Patent Application Publication
(10) Pub. No.: US 2009/0267126 A1
(43) Pub. Date: Oct. 29, 2009

(54) RECESS CHANNEL TRANSISTOR

(76) Inventors: Jer-Chyi Wang, Taoyuan County (TW); Wei-Ming Liao, Taipei City (TW)

Correspondence Address: NORTH AMERICA INTELLECTUAL PROPERTY CORPORATION, P.O. BOX 506, MERRIFIELD, VA, 22116, US

(21) Appl. No.: 12/141,070

(22) Filed: Jun. 17, 2008

(30) Foreign Application Priority Data
Apr. 25, 2008 (TW) 097115290

(51) Int. Cl. H01L 27/108

(52) U.S. Cl. 257/302; 257/E27.091

(57) ABSTRACT

A recess channel transistor includes a semiconductor substrate; a trench isolation region in the semiconductor substrate, which defines an active area; a gate trench in the active area, wherein the gate trench includes a round lower portion; a recessed gate embedded in the gate trench with a spherical gate portion situated in the round lower portion; a gate oxide layer in the round lower portion between the semiconductor substrate and the spherical gate portion; a source region in the active area at one side of the recessed gate; a drain region in the active area at the other side of the recessed gate; and a channel region between the source region and the drain region, wherein the channel region presents a convex curve profile when viewed from a channel widthwise direction.

### BACKGROUND OF THE INVENTION

1. Field of the Invention

The present invention relates generally to semiconductor devices and a method of fabricating the same. More particularly, the present invention relates to a spherical-shaped recess channel transistor structure having saddle-shaped recess channel and recessed gate, which is suited for high-density deep trench capacitor dynamic random access memory (DRAM) devices.

2. Description of the Prior Art

As the size of semiconductor devices shrinks, the gate channel length decreases correspondingly. Consequently, a short channel effect may occur, resulting in problems in increasing the integration of the semiconductor devices and the operating performance. The conventional method of solving the short channel effect includes decreasing the thickness of the gate oxide layer or increasing concentration of the dopants. These methods, however, may deteriorate the reliability of the devices and decrease the speed of transferring data.

To solve the above-mentioned problems, a recessed-gate transistor design or an extended U-shape device (EUD) is used in the semiconductor field to increase the integration of an IC, such as a DRAM, and elevate the operating performance.

The recessed-gate transistor has a gate insulation layer formed on sidewalls and the bottom surface of a recess etched into a substrate, where a conductive substance fills the recess, contrary to a planar gate type transistor having a gate electrode formed on a planar surface of a substrate. Therefore, the integration of the recessed-gate transistor can be increased.

The aforementioned recessed-gate technology has some shortcomings, for, example, capacitance forming between the gate and the drain doping region, or between the gate and the source doping region, gate induced drain leakage (GIDL), insufficient driving current, and poor subthreshold swing. These problems may deteriorate the operating performance of the devices.

### SUMMARY OF THE INVENTION

It is one object of this invention to provide an improved spherical-shaped recessed-gate MOS transistor device with a saddle-shaped recessed gate and recess channel so as to solve the shortcomings of the prior art and to improve the operating performance.

According to the claimed invention, a recess channel transistor structure is provided, which includes a semiconductor substrate; a shallow trench isolation (STI) region in the semiconductor substrate, wherein the STI region defines an active area; a gate trench in the active area, wherein the gate trench comprises a vertical sidewall portion and a spherical-shaped bottom portion; a recessed gate in the gate trench, wherein the recessed gate comprises a spherical-shaped gate bottom situated at the spherical-shaped bottom portion; a gate oxide layer at the spherical-shaped bottom portion, wherein the gate oxide layer is interposed between the spherical-shaped gate bottom and the semiconductor substrate; a source doping region disposed in the active area at one side of the recessed gate; a drain doping region disposed in the active area at the other side of the recessed gate; and a channel region between the source doping region and the drain doping region, wherein the channel region has a convex surface profile when viewed from a gate channel widthwise direction.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing a portion of the layout of a deep trench capacitor DRAM array and a recessed-gate MOS transistor in accordance with one preferred embodiment of this invention.

FIG. 2 depicts schematic, cross-sectional views taken along lines I-I′, II-II′ and III-III′ of FIG. 1, respectively.

FIG. 3 to FIG. 8 are schematic, cross-sectional diagrams showing the process steps for forming the recessed gate and the recess channel according to this invention wherein both of the I-I′ cross-section (the channel lengthwise direction) and II-II′ cross-section (the channel widthwise direction) are presented in each figure.

### DETAILED DESCRIPTION

The present invention will be described more fully hereinafter with reference to the accompanying drawings in which an embodiment of the invention is shown. This invention may, however, be embodied in many different forms and should not be construed as being limited to the embodiment set forth herein. Rather, the embodiment is provided so that this disclosure is thorough and complete and fully conveys the scope of the invention to those skilled in the art, In the drawings, the shapes and forms of elements are exaggerated for clarity.

The present invention pertains to a high-performance spherical-shaped recess channel array transistor (S-RCAT) having saddle-shaped recessed gate, which is suited for high-density deep trench capacitor DRAM devices.

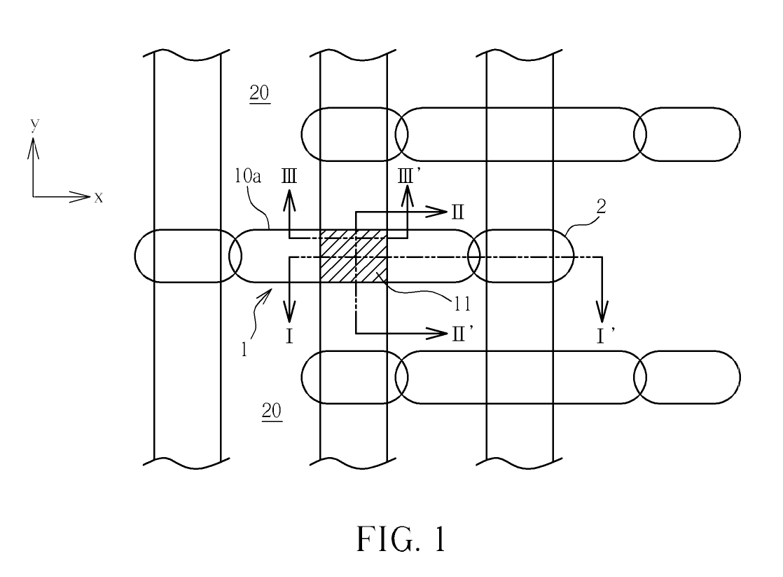

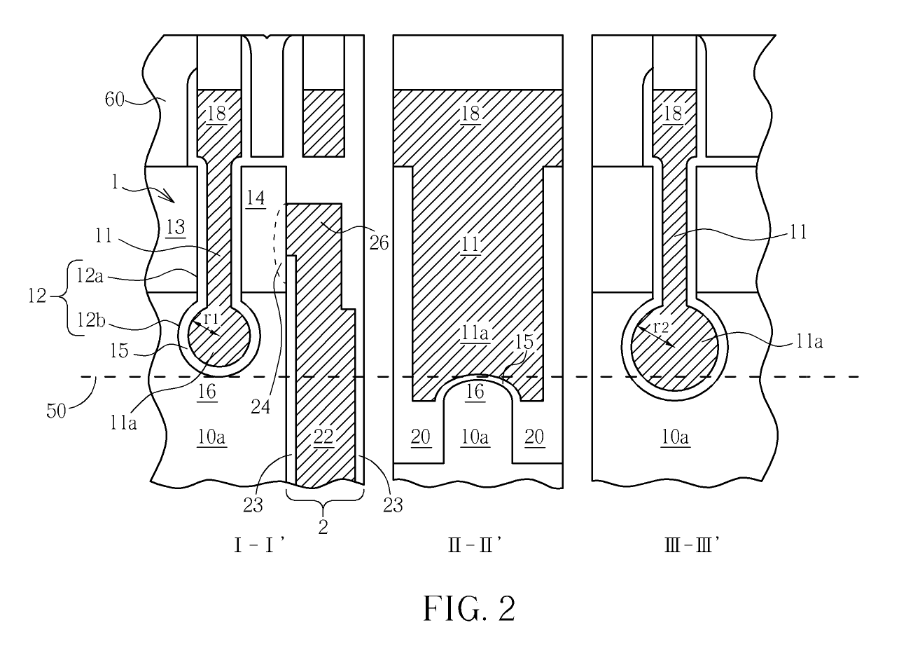

Please refer to FIG. 1 and FIG. 2. FIG. 1 is a schematic diagram showing a portion of the layout of a deep trench capacitor DRAM array and a recessed-gate MOS transistor in accordance with one preferred embodiment of this invention. FIG. 2 depicts schematic, cross-sectional views taken along lines I-I′, II-II′ and III-III′ of FIG. 1, respectively, wherein the I-I′ cross-section and the III-III′ cross-section are both channel lengthwise cross-section (i.e., source-drain direction), while the II-II′ cross-section is a channel widthwise cross-section that is normal to the source-drain direction).

As shown in FIG. 1 and FIG. 2, a recessed-gate MOS transistor device 1 is disposed within a memory array and is fabricated on an active area 10a surrounded by a shallow trench isolation (STI) structure 20. The recessed-gate MOS transistor device 1 and a deep trench capacitor structure 2 that is disposed in very close proximity to the recessed-gate MOS transistor device 1 constitute a memory cell unit.

According to the preferred embodiment of this invention, the recessed-gate MOS transistor device 1 comprises a recessed gate 11, a source doping region 13, a drain doping region 14 and a gate oxide layer 15. The cross-section of the recessed gate 11, when viewed from the gate channel lengthwise direction, is similar to a round-bottom flask, which comprises a spherical-shaped gate bottom 11a embedded in a gate trench 12. The recessed gate 11 may be made of polysilicon, metals or combinations thereof. The gate trench 12 comprises a vertical sidewall portion 12a and a spherical-shaped bottom portion 12b. The spherical-shaped gate bottom 11a is situated in the spherical-shaped bottom portion 12b. The channel region 16 of the recessed-gate MOS transistor device 1 is at the spherical-shaped bottom portion 12b.

According to the preferred embodiment of this invention, the gate oxide layer 15 on the surface of the spherical-shaped bottom portion 12b may be formed by furnace technique, rapid thermal process or any suitable oxide growth technology. In the y direction of the reference coordinate, recess gates 11 on the same column are electrically connected to each other through the gate conductor or word line 18 that transmits voltage signals.

According to the preferred embodiment of this invention, the deep trench capacitor structure 2 comprises a doped polysilicon layer 22 and a sidewall capacitor dielectric layer 23 such as oxide-nitride-oxide (ONO) dielectric layer. The doped polysilicon layer 22 functions as a top electrode of the deep trench capacitor structure 2. For the sake of simplicity, the bottom buried plate or bottom electrode of the deep trench capacitor structure 2 is not shown in the figures and only the upper portion of the deep trench capacitor structure 2 is shown.

Further, the upper portion of the deep trench capacitor structure 2 comprises a single-sided buried strap (SSBS) 26 that is fabricated by single-sided buried strap process, and a trench top oxide (TTO) layer 30. The TTO layer 30 may be composed of silicon oxide such as high-density plasma chemical vapor deposition (HDPCVD) oxide.

The aforesaid SSBS process generally comprises the steps of etching back the sidewall capacitor dielectric layer 23 and the doped polysilicon (or so-called Poly-2) 22 to a first depth; refilling the recess with another layer of polysilicon (or so-called Poly-3); etching back the Poly-3 to a second depth; forming an asymmetric spacer on interior sidewall of the recess; etching away the Poly-3 and Poly-2 that are not covered by the asymmetric spacer; filling the recess with TTO insulation layer; and chemical mechanical polishing the TTO insulation layer.

The recessed-gate MOS transistor device 1 is connected to a diffusion region 24 expanded from the SSBS 26 through the drain doping region 14. The electrons or currents will flow from the bit line (not shown) to a contact plug 40, the source doping region 13 of the recessed-gate MOS transistor device 1, and the channel region 16 which is turned on, then the electrons or currents continue flowing to the drain doping region 14, the diffusion region 24, and finally to the top electrode of the deep trench capacitor 2. In this way, the data storage can proceed.

It is one kernel feature of the present invention that the spherical-shaped gate bottom 11a of the recessed gate 11 has a bended dumbbell shape or a barbell shape when viewed from the gate channel widthwise direction. When viewed from the gate channel widthwise direction, the channel region 16 has a convex surface profile and the three-dimensional structure of the channel region 16 has a saddle-shaped surface.

The horizontal dotted line 50 in FIG. 2 indicates that the I-I′ cross-section is approximately at the highest point of the channel region 16 and the III-III′ cross-section is at relatively lower position and is close to the STI structure 20. At the highest point of the channel region 16 as shown in the I-I′ cross-section, the spherical-shaped gate bottom 11a of the recessed gate 11 has a radius of curve r₁. At the relatively lower position as shown in the III-III′ cross-section, the spherical-shaped gate bottom 11a of the recessed gate 11 has a radius of curve r₂, wherein r₂≧r₁. Further, as shown in the II-II′ cross-section of FIG. 2, the spherical-shaped gate bottom 11a extends into the STI structure 20 to form an extending portion 11b that pinches the channel region 16.

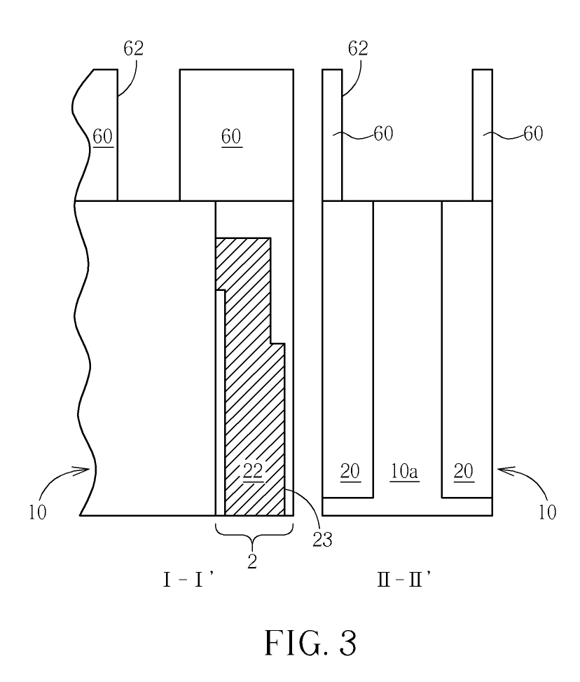

Please refer to FIG. 3 to FIG. 8. FIG. 3 to FIG. 8 are schematic, cross-sectional diagrams showing the process steps for forming the recessed gate and the recess channel according to this invention, wherein both of the I-I′ cross-section (the channel lengthwise direction) and II-II′ cross-section (the channel widthwise direction) are presented in each figure and like numeral numbers designate like elements, regions or layers.

As shown in FIG. 3, a deep trench capacitor structure 2 is fabricated in a semiconductor substrate 10. The deep trench capacitor structure 2 comprises a doped polysilicon layer 22 and a sidewall capacitor dielectric layer 23. Subsequently, a photoresist pattern 60 is formed on the semiconductor substrate 10. The photoresist pattern 60 comprises an opening 62 that defines the pattern and the position of the recessed gate. It is noteworthy that when viewed from the II-II′ cross-section the opening 62 exposes a portion of the STI structure 20 at two opposite sides of the active area 10a.

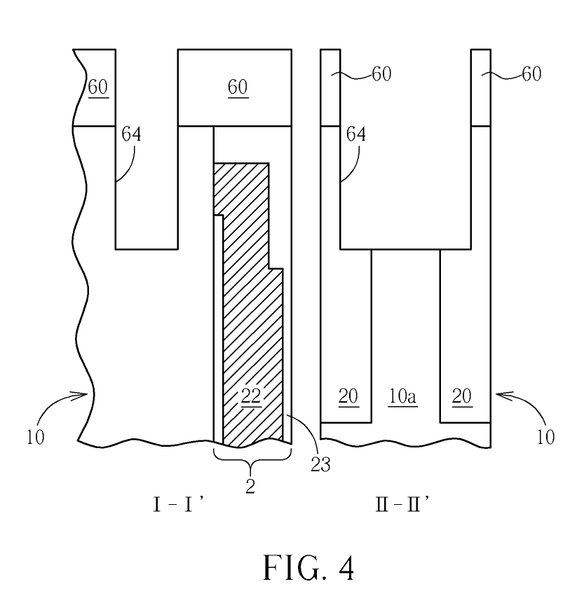

As shown in FIG. 4, thereafter, using the photoresist pattern 60 as an etching hard mask, an anisotropic etching process is performed to anisotropically etch the exposed active area 10a and the exposed STI structure 20 through the opening 62 of the photoresist pattern 60, thereby forming a transitional trench 64. According to the preferred embodiment of this invention, the etchant or plasma that is used in the aforesaid anisotropic etching process may contain CF₄ and oxygen such that the ratio of the etching rate of active area 10a (silicon) to the etching rate of the STI structure 20 (silicon oxide) is approximately 1:1.

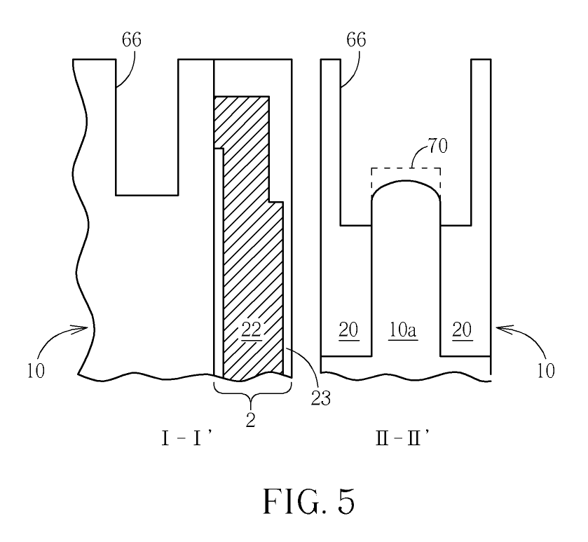

As shown in FIG. 5, using the same photoresist pattern 60 as an etching hard mask, a second anisotropic etching process is performed to selectively etch away a portion of the STI structure 20 through the opening 62 of the photoresist pattern 60, thereby forming a transitional trench 66. It is noteworthy that when performing the aforesaid second anisotropic etching process a portion of the active area 10a is removed, thereby forming a convex, saddle-shaped surface profile. The original active area profile before the second anisotropic etching process is carried out is indicated with dotted line 70.

According to the preferred embodiment of this invention, the etchant or plasma that is used in the aforesaid second anisotropic etching process may contain C₂F₆ and oxygen such that the ratio of the etching rate of active area 10a (silicon) to the etching rate of the STI structure 20 (silicon oxide) is approximately 1:x, wherein x>>1, for example, x ranges between 30 and 100. Subsequently, the remanent photoresist pattern 60 is stripped off.

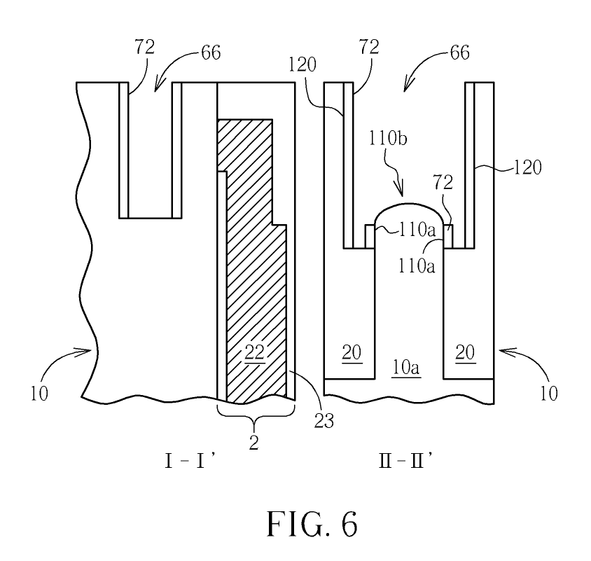

As shown in FIG. 6, a sidewall spacer 72 is formed on the vertical sidewall 110a of the protruding active area 10a and on the vertical sidewall 120 of the transitional trench 66. A saddle-shaped top surface 110b of the protruding active area 10a is exposed. According to the preferred embodiment of this invention, the sidewall spacer 72 may be polymer, but not limited thereto.

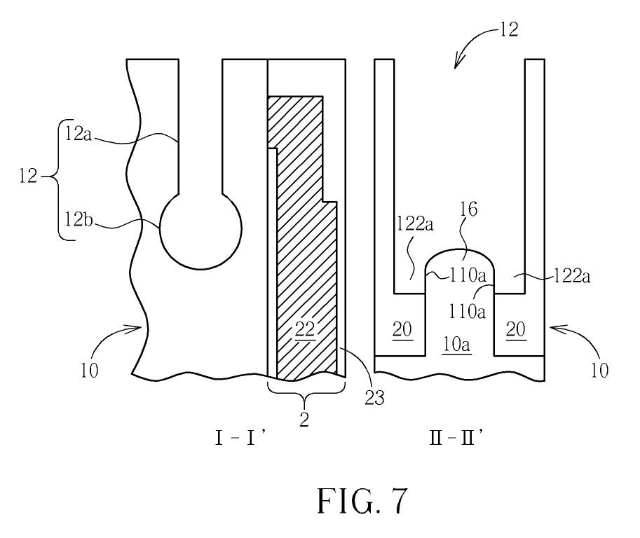

As shown in FIG. 7, an isotropic etching process such as etching process that uses SF₆-containing plasma is carried out to etch the exposed saddle-shaped top surface 110b of the protruding active area 10a, which is not covered by the sidewall spacer 72, thereby forming a gate trench 12 and a channel region 16, wherein the gate trench 12 comprises a vertical sidewall portion 12a and a spherical-shaped bottom portion 12b. Subsequently, the sidewall spacer 72 is removed. From the II-II′ cross-section, it is clear to see that the channel region 16 protrudes from the surrounding STI structure 20 and recesses 122a are formed between the active area 10a and the STI structure 20. A portion of the vertical sidewalls 110a of the active area 10a is exposed.

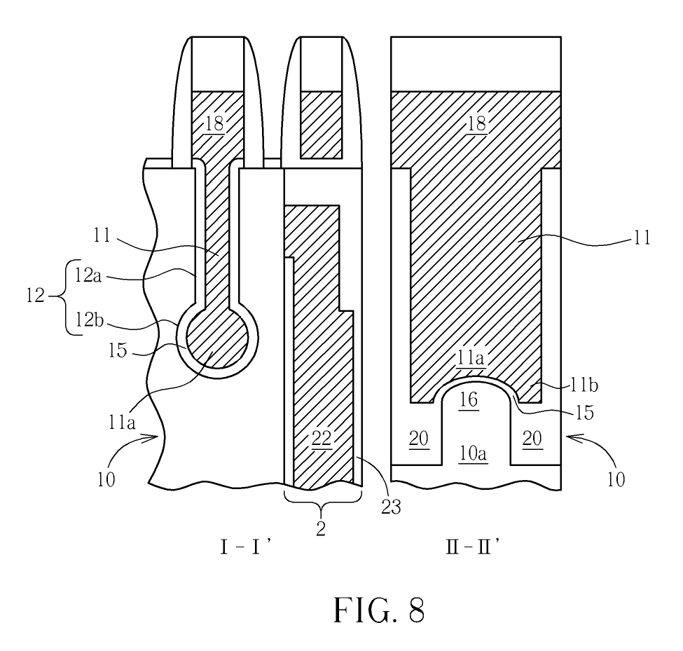

Finally, as shown in FIG. 8, a gate oxide layer 15 is formed on the surface of the spherical-shaped bottom portion 12b of the gate trench 12. From the II-II′ cross-section, it is clear to see that the gate oxide layer 15 is formed on the channel region 16 and the vertical sidewall 110a. After the formation of the gate oxide layer 15, a recessed gate 11 is formed inside the gate trench 12 and a gate conductor or word line is formed atop the recessed gate 11, wherein the recessed gate 11 comprises a spherical-shaped gate bottom 11a and an extending portion 11b formed on the vertical sidewall 110a.

Those skilled in the art will readily observe that numerous modifications and alterations of the device and method may be made while retaining the teachings of the invention.

What is claimed is:

1. A recess channel transistor structure, comprising:
a semiconductor substrate;
a shallow trench isolation (STI) region in the semiconductor substrate, wherein the STI region defines an active area;
a gate trench in the active area, wherein the gate trench comprises a vertical sidewall portion and a round lower portion;
a recessed gate in the gate trench, wherein the recessed gate comprises a spherical gate portion situated in the round lower portion;
a gate oxide layer at the round lower portion, wherein the gate oxide layer is interposed between the spherical gate portion and the semiconductor substrate;
a source doping region disposed in the active area at one side of the recessed gate;
a drain doping region disposed in the active area at the other side of the recessed gate; and
a channel region between the source doping region and the drain doping region, wherein the channel region has a convex surface profile when viewed from a gate channel widthwise direction.

2. The recess channel transistor structure according to claim 1 wherein the spherical gate portion has a bended dumbbell shape when viewed from the gate channel widthwise direction.

3. The recess channel transistor structure according to claim 2 wherein at a highest point of the channel region, the spherical gate portion has a radius of curve r₁, and at a relatively lower position, the spherical gate portion has a radius of curve r₂, and wherein r₂≧r₁.

4. The recess channel transistor structure according to claim 1 wherein the channel region further comprises a vertical sidewall in a gate channel widthwise direction.

5. The recess channel transistor structure according to claim 4 wherein the recessed gate further comprises an extending portion on the vertical sidewall.

6. The recess channel transistor structure according to claim 5 wherein the extending portion extends into the STI structure.

7. The recess channel transistor structure according to claim 1 wherein the recessed gate comprises polysilicon, metal or combination thereof.

8. The recess channel transistor structure according to claim 1 wherein the recessed gate has a cross-section that is similar to a round-bottom flask when viewed from a gate channel lengthwise direction.

9. The recess channel transistor structure according to claim 1 wherein the recess channel transistor structure and a deep trench capacitor structure that is disposed in very close proximity to the recess channel transistor structure constitute a memory cell unit.
